(19) United States
(12) Patent Application Publication
(10) Pub. No.: US 2007/0009815 A1
(43) Pub. Date: Jan. 11, 2007

(54) METHOD OF WAFER EDGE EXPOSURE

(75) Inventors: Gyeong-Hwan OH, Seoul (KR); Hee-Sun CHAE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do (KR)

(21) Appl. No.: 11/428,797

(22) Filed: Jul. 5, 2006

(30) Foreign Application Priority Data
Jul. 6, 2005 (KR) 2005-0060849

(51) Int. Cl. G03F 7/20

(52) U.S. Cl. 430/30; 430/311

(57) ABSTRACT

In an embodiment, a method of wafer edge exposure includes sensing a reference position of a wafer edge exposure. A boundary for the edge exposure is set at a predetermined distance from the reference position, and then the edge region of the wafer is exposed. A first boundary for the first edge exposure can be set on the basis of the edge of the wafer, and a boundary for a next edge exposure can be set on the basis of the boundary in the previous edge exposure.

### CROSS-REFERENCE TO RELATED APPLICATIONS

This application hereby claims priority under 35 U.S.C. § 119 to Korean Patent Application 2005-60849 filed on Jul. 6, 2005, of which the entire contents are hereby incorporated herein by reference.

### BACKGROUND

1. Field of the Invention

The present invention relates to a process of manufacturing a semiconductor device, and more particularly, to a method of wafer edge exposure.

2. Description of the Conventional art

In manufacturing processes of semiconductor devices, a photolithography process generally includes a coating process to coat a photoresist on a wafer, an exposure process to selectively expose the coated photoresist through a reticle, and a development process to develop the exposed photoresist to form a photoresist pattern.

At an edge portion of the wafer, patterns are typically formed with irregular size and with a low adhesion between the wafer and a thin film. Because of this low adhesion, material formed on the edge of the wafer may be detached during a process, and the detached material may end up being adhered onto an effective area of the wafer. This can easily result in a pattern failure, causing a defective product as well as contaminating the manufacturing apparatuses.

The photoresist coating process includes exposing an edge of a wafer, hereinafter referred to as a “wafter edge exposure (WEE)” or “edge exposure wafer (EEW)” process. In the WEE process, the edge of the wafer is exposed and then a material layer around the edge of the wafer is etched. When the WEE is performed during the photoresist coating process, a WEE area with a predeteimined width is formed on an edge portion of the wafer 10 as shown in FIG. 1. For the material layer formed in the present step to selectively cover or not to cover a boundary of the edge exposure wafer of a previous step, the width of the processed portion of the wafer, hereinafter referred to as the “processed wafer”, must be properly set.

FIG. 2 is a schematic view illustrating a method for setting a width of a wafer edge exposure according to the conventional art.

Referring to FIG. 2, the wafer must be centered before performing the WEE process. In the conventional art, the centering is performed by calculating a distance from a wafer center CW to an edge A0 of the wafer according to a size of the wafer. In the case of 300 mm wafer, for example, an imaginary edge A0 is set 150 mm away from the center CW of the wafer.

In a first WEE step, the WEE is performed by setting a first boundary A1 a predetermined distance EEW0 away from the edge A0 of the processed wafer.

The WEE process has a specific position error ‘e’ depending on an exposure apparatus. Therefore, the first boundary A1 of the processed wafer is formed at a distance of EEW0±4e from the edge A0 of the wafer. In a second WEE process, a second boundary A2 of the processed wafer is set at a distance of EEW0±2e from the edge A0 of the wafer, adding the position error ‘e’ of the first WEE process and a position error ‘e’ of the second WEE process. Also, in a third WEE process, a third boundary A3 of the processed wafer is set at a distance of EEWG±4e from the edge A0 of the wafer, adding the position error ‘e’ of the second WEE process and a position error ‘e’ of the third WEE process.

In the WEE method according to conventional art, the respective boundaries for the WEE are set by a calculation from the wafer edge. Thus, the conventional art WEE method has a tolerance, which corresponds to the sum of the position error of the previous WEE and the position error of the current WEE. Thus, to allow the boundary for the WEE of the current step to coincide with the boundary for the WEE of the previous step or to be more distanced from the edge of the wafer, a boundary An for the WEE of n-th step is set at a distance of EEW0±2(n−1)e from the wafer edge A0. That is, in the process of repeating WEE, a required width for the WEE increases by a tolerance ‘2e’ corresponding to a sum of the position errors of the apparatus, so that an effective area on the wafer decreases.

### SUMMARY

Some embodiments of the present invention provide a wafer edge exposure method that can reduce a tolerance in setting an exposure boundary.

Some embodiments also provide a wafer edge exposure method that can reduce a width necessary for the edge exposure wafer.

Embodiments provide methods of sensing a reference position and setting a boundary of an edge exposure wafer on the reference position.

The methods include sensing a reference position of the edge exposure wafer. A boundary for the edge exposure wafer is set at a predetermined distance from the reference position, and then the edge of wafer is exposed. A first boundary for the first edge exposure can be set on the basis of the edge of the wafer, and a boundary for a next edge exposure can be set on the basis of the boundary for the previous edge exposure.

The reference position can be easily sensed by, for example, measuring a change of an optical signal using an optical sensor. For instance, the edge of the wafer can be sensed from a boundary between a region where a light emitting from a light emitting part installed over the wafer is blocked by the wafer, and a region where the light emitting from light emitting part is incident into a light receiving part installed below the wafer. A boundary of the edge exposure wafer in a previous step can be sensed by when a light is illuminated onto the wafer, measuring a signal change of a reflected light at the boundary of the edge exposure wafer.

### BRIEF DESCRIPTION OF THE DRAWINGS

The accompanying drawings, which are included to provide a further understanding of the invention and incorporated in and constitute a part of this application, illustrate embodiment) and together with the description serve to explain the principle of the invention. In the drawings:

FIG. 1 is a plan view of an edge exposure wafer;

FIG. 2 is a partial cross-sectional view illustrating a method of exposing an edge of a wafer according to the conventional art;

FIG. 3 is a partial cross-sectional view illustrating a method of an edge of a wafer according to an embodiment;

FIGS. 4 and 5 are flowcharts illustrating the method of exposing an edge of a wafer according to an embodiment, respectively; and

FIGS. 6 to 8 are partial cross-sectional views of an edge exposure wafer according to embodiments, respectively,

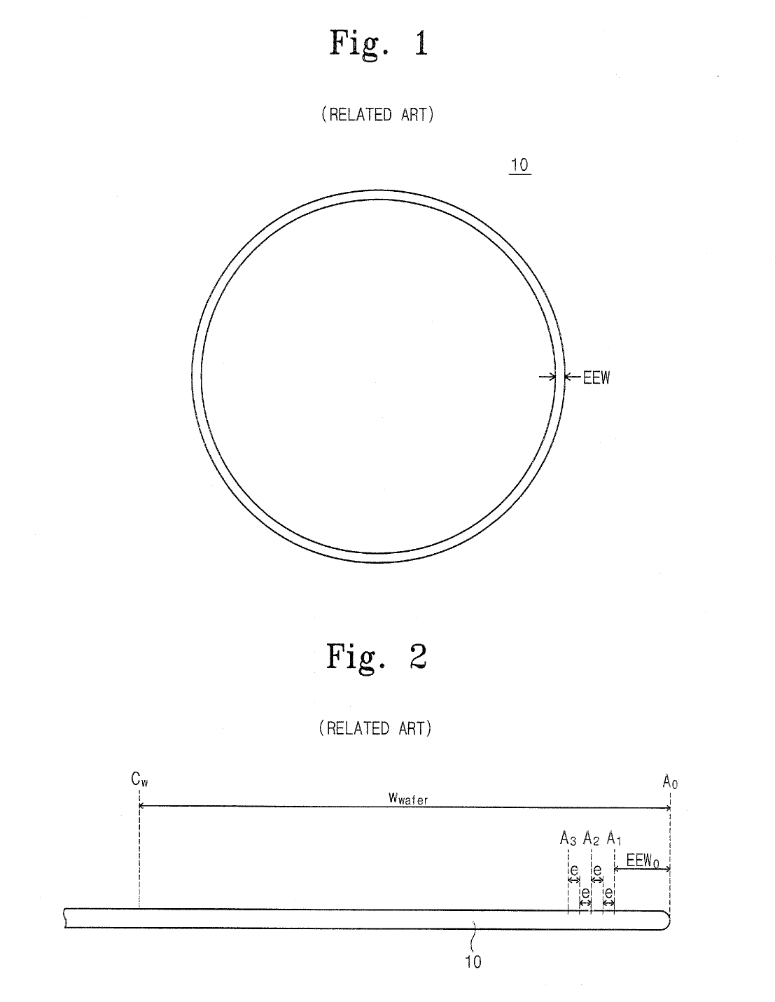

### DETAILED DESCRIPTION

Reference will now be made in detail to the preferred embodiments of the present invention, examples of which are illustrated in the accompanying drawings. However, the present invention is not limited to the embodiments illustrated herein after, and the embodiments herein are rather introduced to provide easy and complete understanding of the scope and spirit of the present invention. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

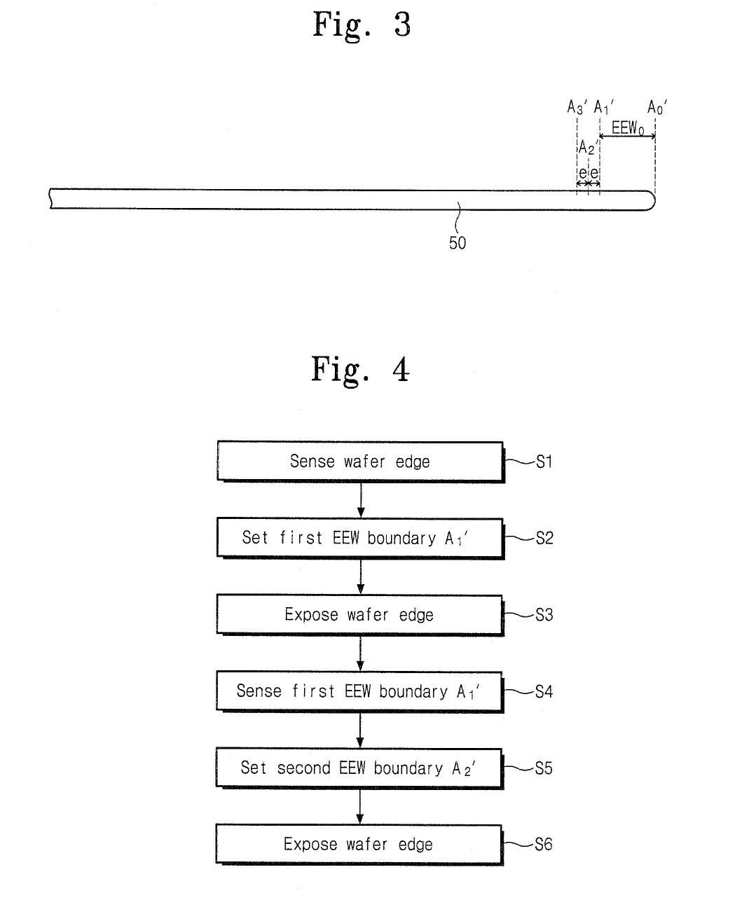

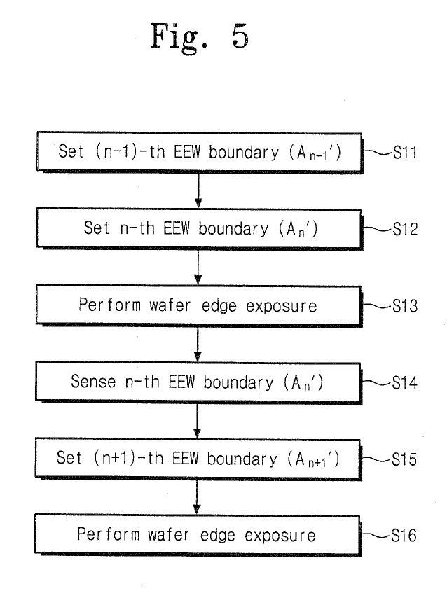

FIG. 3 is a partial cross-sectional view illustrating a method of exposing an edge of a wafer according to a preferred embodiment, and FIGS. 4 and 5 are flowcharts illustrating a method of exposing an edge of a wafer according to the embodiments, respectively.

Referring to FIGS. 3 and 4, in a first WEE step (S1), an edge A0′ of a wafer is sensed and the sensed edge A0′ is set as a reference position. In the conventional art, the imaginary wafer edge A0 is set as the reference position by calculating the distance from a center of a wafer to an edge of the wafer edge. However, in the present embodiment, the real edge A0′ of the wafer is directly sensed as the reference position. The wafer edge can be sensed using an optical sensor. For example, a light emitting device and a light-receiving device each including two-dimensional pixels may be disposed respectively over and below the wafer to face each other. While light is incident from the light emitting device to the light receiving device, the edge of the wafer is sensed using the first pixel where the light is blocked by the wafer. Also, various methods using a scanning light, such as a laser scanning method, can be used to sense the edge of the wafer.

In step S2, a first boundary A1′ for the WEE is set at a distance of EEW0′ from the sensed real edge A0′ of the wafer. A region between the real edge A0′ of the wafer and the first boundary A1′, i.e., EEW0′, becomes a first WEE area.

In step S3, the edge of the wafer, i.e., the width ‘EEW0’ between the wafer edge A0′ and the first boundary A1′, is exposed to light. The edge of the wafer edge maybe exposed by illuminating an ultraviolet ray or a laser beam onto a photoresist layer coated on the wafer. The wafer on which the WEE has been performed may be moved to an exposure process exposing the photoresist film of an effective area using a reticle and a development process developing the exposed photoresist film to form a photoresist pattern. Continuously, various processes may be performed. The process includes an etching process using the photoresist pattern as an etching mask, a photoresist pattern removing process, and a layer forming process.

When a second WEE process is required during the manufacture process of a semiconductor device, a wafer centering is performed so that a center of the wafer is located on a center of a rotating chuck. In the first WEE step, as explained above, the edge A0′ of the wafer is sensed as the reference point. However, in the second WEE step (S4), the real edge A0′ of the wafer is not sensed, but instead a boundary A1′ of the first edge-exposed wafer is sensed. When an etching process is performed using the photoresist pattern with the edge of the wafer being exposed in the previous process, a boundary of the edge exposure wafer is transferred into a lower layer. The reference position of the current step is set by sensing the boundary of the edge exposure wafer in the previous step, i.e., the boundary of the edge exposure wafer of the previous step, which is transferred into the lower layer.

As described above, the real edge of the wafer can be sensed by installing the light emitting device and the light receiving device over and below the wafer to face each other and using a signal of when light is blocked by the wafer. Unlike this, the boundary of the edge exposure wafer of the previous step can be sensed using an apparatus having a different construction. That is, the boundary of the edge exposure wafer of the previous step can be measured by the light emitting sensor disposed over the wafer to illuminate light onto the wafer and the light-receiving sensor sensing a reflected light of which signal is changed by an irregular reflection or a dispersion.

In step S5, a second boundary A2′ of the edge exposure wafer is set at a predetermined distance from the first boundary A1′ of the edge exposure wafer. The second boundary A2′ of the processed wafer is set at a distance of position error ‘e’ from the first boundary A1′ of the processed wafer. Therefore, the second boundary A2′ of the processed wafer is at a distance of EEW0′±e from the real edge of the wafer. Since the conventional art method calculates a boundary An of the processed wafer from the imaginary wafer edge A0, it requires a width corresponding to the tolerance 2e, which is the sum of the current position error and the previous position error. However, since the inventive method sets the current exposure boundary A2′ on the basis of the previous exposure boundary A1′, it can perform the WEE process, considering only the position error of the apparatus. In step S6, the WEE process is performed by applying the second boundary A2′ of the wafer.

While semiconductor devices are manufactured the WEE process is repeated several times. After the first WEE is performed, the current boundary for the WEE can be set on the basis of the previous boundary for the WEE.

Referring to FIGS. 3 and 5, in step S11, an (n−1)-th boundary An-i ’ for an n-th WEE is sensed. In step S12, the n-th boundary An′ is set on the basis of the (n−1)-th boundary An−1′. The n-th boundary An′ can be set at a distance of the position error ‘e’ of the apparatus from the (n−1)-th boundary An−1′. In step S13, the WEE process is performed on the basis of the n-th boundary An′.

The semiconductor manufacturing process may continue to be performed, and in step S14, the n-th boundary An′ for an (n+1)-th WEE step is sensed. In step S15, the (n+1)-th boundary An+1′ is set on the basis of the n-th boundary An′. The (n+1)-th boundary An+1′ can be set at a distance of the position error ‘e’ of the apparatus from the n-th boundary An′. In step S16, the WEE process is performed on the basis of the (n+1)-th boundary An+1′.

To perform n WEE processes, the conventional art method requires the width of the processed wafer corresponding to EEW0+2(n−1)e from the edge of the wafer. However, the method of the present embodiment requires the width of processed wafer corresponding to EEW0+(n−1)e to perform WEE n times. That is, the inventive method results in additional useful wafer area corresponding to the width of (n−1)e, compared with the conventional art method.

Thus, by performing WEE, the method of the present embodiment can remove irregular patterns and/or a layer having poor adhesiveness to prevent the patterns formed on the effective area and the manufacturing apparatus from being contaminated. The semiconductor device includes various materials, such as a material poorly adhered to a wafer, a material strongly adhered to an underlying layer, an insulating material, a conductive material, and the like. Therefore, it may be advantageous to cover a lower layer with an upper layer at an edge of the wafer, or expose a lower layer beside an upper layer.

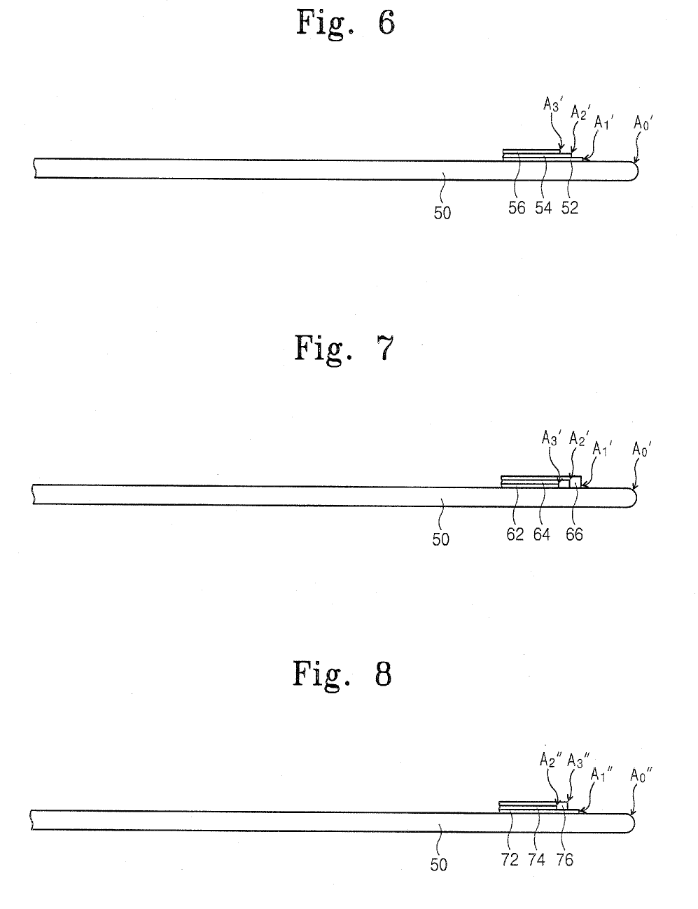

As shown in FIGS. 6 through 8, the present embodiment can be applied many ways. For example, a structure with a lower layer that can be exposed beside an upper layer at the edge of the wafer as shown in FIG. 6. Also shown in FIG. 7 is a structure with a lower layer that is covered with an upper layer, and a structure that can have any layer covering a lower layer and another layer while the lower layer is exposed beside an upper layer, as in FIG. 8.

Embodiments can be applied to the structure so that boundaries A1′, A2′ and A3′ of layers 52, 54 and 56 are distanced from the edge of the wafer as it goes upward as shown in FIG. 6. At this time, each boundary is within the position error ‘e’ of the apparatus and thus a width of the processed wafer is smaller than that of conventional wafer. Also, embodiments can be applied to the structure so that boundaries A1′, A2′ and A3′ of layers 62, 64 and 66 are close to the edge A0′ of the wafer as it goes upwards, as shown in FIG. 7. In this case, each boundary is separated within the position error ‘e’ of the apparatus.

FIG. 8 shows that a first layer 72 is exposed from beyond a second layer 74 and the second layer 74 is covered with a third layer 76. In this case, a boundary A2″ of the second layer 74 is set on the basis of a boundary A1″ of the first layer 72. However, considering the position of the third layer 76, the boundary A2″ of the second layer 74 is set at a distance of twice-error (2e) as much as the position error from the first layer boundary A1″. Also, the boundary A3″ of the third layer 76 can be set at a distance of the position error ‘e’ on the basis of the boundary A2″ of the second layer 74.

As described above, according to some embodiments, the width required for the WEE can be decreased and the effective area on the wafer can be increased. Therefore, when the semiconductor devices having the same chip area are manufactured, the number of chips obtained from the wafer is increased compared with that of the conventional art.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of wafer edge exposure, the method comprising:
sensing a reference position for a wafer edge exposure process;
setting a boundary for the wafer edge exposure process at a predetermined distance from the reference position; and
exposing a region from the reference position to the boundary for the wafer edge exposure.

2. The method according to claim 1, wherein the reference position is sensed by measuring an optical signal which is changed at the boundary of the wafer edge exposure process using an optical sensor.

3. The method according to claim 1, wherein an edge of the wafer is set as the reference position for a first wafer edge exposure.

4. The method according to claim 1, wherein a boundary of the wafer edge exposure process in a previous step is set as the reference position of the wafer edge exposure process in a current step.

5. The method according to claim 1, wherein the boundary of the wafer edge exposure process is set at a distance of a position error from the reference position.

6. A method of wafer edge exposure, the method comprising:
centering the wafer;
sensing the edge of the wafer;
setting a boundary of the wafer edge exposure at a predetermined distance from the edge of the wafer; and
exposing the region from the edge of the wafer to the boundary of the wafer edge exposure.

7. The method according to claim 6, wherein the edge of the wafer is sensed by measuring an optical signal that is changed at the edge of the wafer using an optical sensor.

8. The method according to claim 7, wherein the edge of the wafer is sensed by measuring an optical signal on one side of the wafer that is changed at the edge of the wafer using a light source on the other side of the wafer..

9. A method of wafer edge exposure, the method comprising:
centering the wafer;
sensing a first boundary in a previous edge exposure step of the wafer;
setting a second boundary for a current edge exposure step at a predetermined distance from the first boundary; and
exposing the region from the edge of the wafer to the second boundary.

10. The method according to claim 9, wherein the first boundary in the previous wafer edge exposure step is sensed by measuring an optical signal which is changed at the first boundary using an optical sensor.

11. The method according to claim 10, wherein the first boundary for the previous edge exposure step is sensed by a light receiving device sensing a change of the optical signal which emits from a light emitting sensor installed on one side of the edge exposure wafer.

12. The method according to claim 9, wherein the second boundary for the current edge exposure step is set at a distance of a position error from the first boundary for the previous edge exposure step.
